(19) United States
(12) Patent Application Publication
(10) Pub. No.: US 2014/0327156 A1
(43) Pub. Date: Nov. 6, 2014

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventor: Taejoo HWANG, Hwasung-City (KR)

(73) Assignee: SAMSUNG ELECTRONICS CO., LTD., Suwon-si (KR)

(21) Appl. No.: 14/136,928

(22) Filed: Dec. 20, 2013

(30) Foreign Application Priority Data
May 2, 2013 (KR) 10-2013-0049507

(51) Int. Cl. H01L 23/34; H01L 25/065

(52) U.S. Cl. CPC H01L 23/34; H01L 25/0657
USPC 257/777

(57) ABSTRACT

Provided are a semiconductor package and a method for manufacturing the same. The semiconductor package may include a substrate, a lower semiconductor chip disposed on an inner surface of the substrate, and an upper semiconductor chip disposed on the lower semiconductor chip. A plurality of connection terminals may be disposed between the substrate and the lower semiconductor chip to electrically connect the lower semiconductor chip to the substrate. The upper semiconductor chip may have a lower surface which faces the substrate and an upper surface which opposes the lower surface. Bonding wires may pass through the windows to connect the lower surface of the upper semiconductor chip to an outer surface of the substrate.

### CROSS-REFERENCE TO RELATED APPLICATIONS

This application claims priority from Korean Patent Application No. 10-2013-0049507, filed on May 2, 2013, the entire contents of which is hereby incorporated by reference in its entirety.

### BACKGROUND

Exemplary embodiments related to a semiconductor. In particular, exemplary embodiments relate, to a semiconductor package and a method for manufacturing the same.

With the development of the electronics industry, light, small, high-speed, and high-performance electronic products have been provided at a low price. An integrated circuit chip is packaged into a semiconductor package to be installed in an electronic device. Therefore, reliability of the semiconductor package must be improved. In particular, thermal characteristics and electrical characteristics of the semiconductor package must be improved.

### SUMMARY

Exemplary embodiments provide a reliable semiconductor package with improved heat dissipation of a semiconductor chip.

Exemplary embodiments also provide a high-performance semiconductor package with reduced parasitic capacitance between semiconductor chips.

According to an aspect of an exemplary embodiment, there is provided a semiconductor package including a substrate having an outer surface and an inner surface which opposes the outer surface, wherein the substrate is provided with a plurality of windows which pass through the inner surface and the outer surface, a lower semiconductor chip disposed on the inner surface of the substrate, an upper semiconductor chip disposed on the lower semiconductor chip, wherein the upper semiconductor chip has a lower surface which faces the substrate and an upper surface which opposes the lower surface, a plurality of connection terminals disposed between the substrate and the lower semiconductor chip, wherein the connection terminals electrically connect the lower semiconductor chip to the substrate, and a plurality of bonding wires which pass through the windows and connect the lower surface of the upper semiconductor chip to the outer surface of the substrate.

In some embodiments, the semiconductor packages may further include a heat slug disposed on the upper surface of the upper semiconductor chip, and a heat transfer layer disposed between the upper semiconductor chip and the heat slug.

In other embodiments, the upper semiconductor chip may include a plurality of connection pads disposed on both ends of the lower surface of the upper semiconductor chip to contact the bonding wires, and wherein the lower semiconductor chip may expose the connection pads.

In still other embodiments, the windows may be arranged in a vertical location in relation to the connection pads.

In even other embodiments, a plane of the lower semiconductor chip may have a longitudinal axis extending in one direction, and a plane of the upper semiconductor chip may have a longitudinal axis extending in another direction which is different from the one direction.

In yet other embodiments, the semiconductor packages may further include a molding layer disposed on the inner surface of the substrate, wherein the molding layer may seal the lower semiconductor chip, the upper semiconductor chip, the connection terminals, and the bonding wires.

According to an aspect of another exemplary embodiment, there is provided a method for manufacturing a semiconductor package including disposing, on a heat slug, an upper semiconductor chip having a first surface provided with a plurality of connection pads and a second surface which opposes the first surface, disposing a substrate having an outer surface and an inner surface which opposes the outer surface, wherein a plurality of substrate pads are disposed on the outer surface and a lower semiconductor chip is mounted on the inner surface using a plurality of connection terminals, attaching the lower semiconductor chip to the first surface of the upper semiconductor chip so as to expose the connection pads, and forming a plurality of bonding wires which contact the connection pads and the substrate pads, wherein the bonding wires electrically connect the upper semiconductor chip to the substrate, wherein the second surface of the upper semiconductor chip faces the heat slug.

In some embodiments, the disposing the upper semiconductor chip may include forming a heat transfer layer on the heat slug, and disposing the upper semiconductor chip on the heat transfer layer so that the second surface faces the heat slug.

In other embodiments, the forming the bonding wires may include disposing the upper semiconductor chip so that the second surface faces down.

In still other embodiments, the substrate may have a plurality of windows which pass through the inner surface and the outer surface of the substrate, and wherein the forming the bonding wires may include connecting the upper semiconductor chip to the substrate through the windows.

According to an aspect of yet another exemplary embodiment, there is provided a semiconductor package including a substrate which comprises a plurality of windows passing through the substrate, a lower semiconductor chip disposed on the substrate, an upper semiconductor chip disposed on the lower semiconductor chip, and a heat slug disposed on the upper semiconductor chip, wherein the upper semiconductor chip is electrically connected to the substrate through a plurality of connection terminals.

In even other embodiments, the attaching the lower semiconductor chip may include arranging the lower semiconductor chip and the substrate so that the inner surface of the substrate faces the upper semiconductor chip.

### BRIEF DESCRIPTION OF THE DRAWINGS

The accompanying drawings are included to provide a further understanding of the exemplary embodiments, and are incorporated in and constitute a part of this specification. The drawings illustrate exemplary embodiments and, together with the description, serve to explain principles of the exemplary embodiments. In the drawings:

FIG. 1 is a planar view illustrating a semiconductor device according to an embodiment;

FIG. 2 is a cross-sectional view of the semiconductor device taken along the line A-B of FIG. 1;

FIG. 3 is a planar view illustrating a semiconductor device according to another embodiment;

FIG. 4 is a cross-sectional view of the semiconductor device taken along the line A-B of FIG. 3;

FIG. 5 is a planar view illustrating a semiconductor device according to another embodiment;

FIG. 6 is a cross-sectional view of the semiconductor device taken along the line A-B of FIG. 5;

FIG. 7 is a planar view illustrating a semiconductor device according to another embodiment;

FIG. 9 is a cross-sectional view illustrating a semiconductor package according to an embodiment;

FIGS. 10 to 13 illustrate a method for manufacturing a semiconductor device according to an embodiment;

FIG. 14 is a block diagram illustrating an electronic device including a semiconductor package to which the technology is applied; and

FIG. 15 is a block diagram illustrating a memory system including a semiconductor package to which the technology is applied.

### DETAILED DESCRIPTION OF THE EXEMPLARY EMBODIMENTS

Exemplary embodiments will be described below in more detail with reference to the accompanying drawings. Exemplary embodiments may, however, be embodied in different forms and should not be construed as limited to the embodiments set forth herein. Rather, these embodiments are provided so that this disclosure will be thorough and complete, and will fully convey the scope of the exemplary embodiments to those skilled in the art.

The terminology used herein is not for delimiting the embodiments, but for describing the embodiments. The terms of a singular form may include plural forms unless otherwise specified. The meaning of “include,” “comprise,” “including,” or “comprising,” specifies a property, a region, a fixed number, a step, a process, an element and/or a component but does not exclude other properties, regions, fixed numbers, steps, processes, elements and/or components.

In this description, when a film (or layer) is referred to as being ‘on’ another film (or layer), it can be directly on the other film (or layer), or intervening films (or layers) may also be present.

Relational terms such as “first”, “second”, “third”, and the like may be used for describing various regions and films (or layers), but the regions and films should not be limited by the terms. These terms are merely used to distinguish a certain region or film (or layer) from another region or film (or layer). Therefore, a film material referred to as a first film material in an embodiment may be referred to as a second film material in another embodiment. The embodiments exemplified and described herein include complementary embodiments thereof. Like reference numerals refer to like elements throughout.

The terms used to describe the embodiments of the inventive concept may be interpreted as the meanings known in the art unless the terms are defined differently.

Hereinafter, a semiconductor device according to an embodiment will be described.

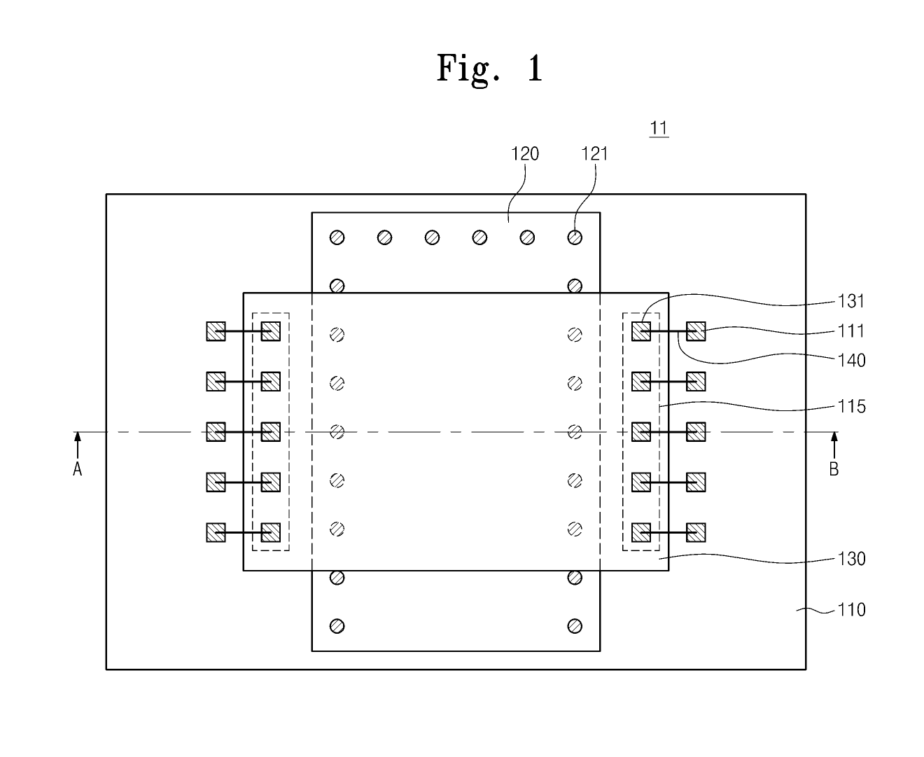

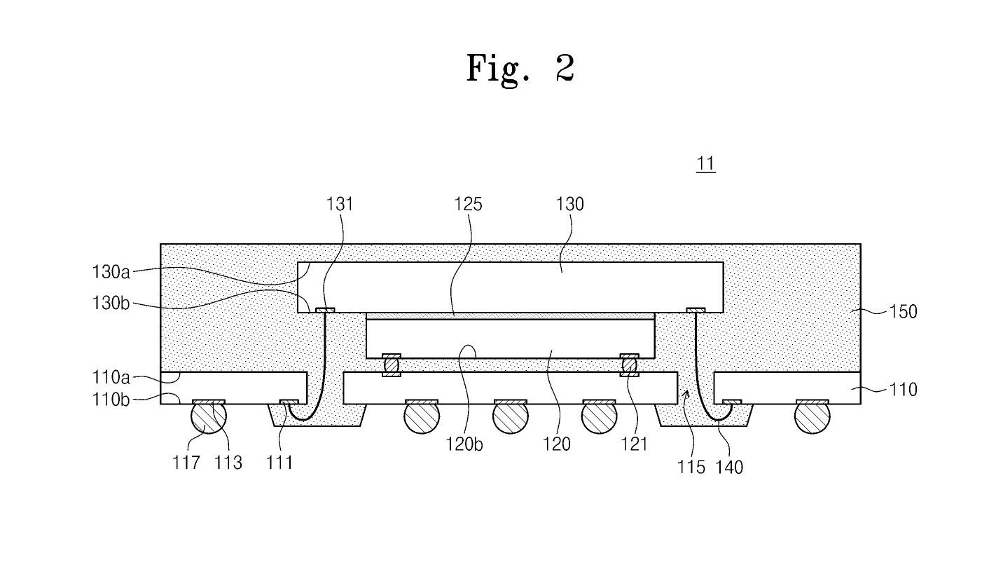

FIG. 1 is a planar view illustrating the semiconductor device according to an embodiment. FIG. 2 is a cross-sectional view of the semiconductor device taken along the line A-B of FIG. 1.

Referring to FIGS. 1 and 2, a semiconductor device 11 may include a substrate 110, first bumps 121, a lower semiconductor chip 120, an upper semiconductor chip 130, and bonding wires 140.

The substrate 110 may be a printed circuit board (PCB) having circuit patterns. The substrate 110 may have an inner surface 110a and an outer surface 110b opposing each other. Windows 115 which pass through the substrate 110 from the inner surface 110a to the outer surface 110b may be provided. The windows 115 are arranged in pairs at corresponding positions, and may have quadrangular cross sections. First pads 111 and second pads 113 may be provided on the outer surface 110b. The first pads 111 may be arranged to be closer to the windows 115 than the second pads 113. Solder balls 117 may be provided on the second pads 113. The second pads 113 and the solder balls 117 may electrically connect the substrate 110 to an external device. The first pads 111, the second pads 113, and/or the solder balls 117 may include conductive materials.

The lower semiconductor chip 120 may be provided on the inner surface 110a of the substrate 110. The lower semiconductor chip 120 may be arranged on a center of the substrate 110. The lower semiconductor chip 120 may have a quadrangular plane. The lower semiconductor chip 120 may include an integrated circuit, e.g., a memory circuit, a logic circuit, or a combination thereof. A lower surface 120b of the lower semiconductor chip 120 may be an active surface.

The first bumps 121 are arranged between the substrate 110 and the lower semiconductor chip 120 and may electrically connect the lower semiconductor chip 120 to the substrate 110. For example, the first bumps 121 may be arranged on an edge of the lower semiconductor chip 120. In another example, the first bumps 121 may be arranged on a center of the lower semiconductor chip 120. In another example, the first bumps 121 may be arranged uniformly on the lower surface 120b of the lower semiconductor chip 120. The first bumps 121 may include conductive materials. In the case where the lower semiconductor chip 120 is mounted on the substrate 110 by wire, it may be difficult to dissipate heat generated from the lower semiconductor chip 120 to the outside. The first bumps 121 may dissipate the heat generated from the lower semiconductor chip 120 to the substrate 110. Therefore, operation reliability of the lower semiconductor chip 120 may be improved.

The upper semiconductor chip 130 may be provided on the lower semiconductor chip 120. An adhesive film 125 may be disposed between the upper semiconductor chip 130 and the lower semiconductor chip 120 to attach the upper semiconductor chip 130 to the lower semiconductor chip 120. The adhesive film 125 may include an insulative polymer. The upper semiconductor chip 130 may have an upper surface 130a and a lower surface 130b opposing each other. The upper surface 130a may be an inactive surface. The lower surface 130b faces the substrate 110 and may serve as an active surface. Third pads 131 may be arranged on the lower surface 130b of the upper semiconductor chip 130. Third pads 131 may serve to connect the upper semiconductor chip 130 to the bonding wires 140. For example, the third pads 131 may be provided to both ends of the upper semiconductor chip 130. The third pads 131 may be arranged on a location vertically corresponding to the windows 115 of the substrate 110. The third pads 131 may be arranged in the same directions as those of longitudinal axes of cross sections of the windows 115.

The bonding wires 140 may contact the third pads 131 and the first pads 111 to electrically connect the upper semiconductor chip 130 to the substrate 110. The windows 115 may serve as passages of the bonding wires 140. The bonding wires 140 may include conductive materials (e.g., gold). In the case where the upper semiconductor chip 130 is connected to the lower semiconductor chip 120 by solder or bump, the lower semiconductor chip 120 may have a via that passes therethrough. Since the semiconductor device 11 according to an embodiment includes the bonding wires 140, damage to the lower semiconductor chip 120 due to the forming of the via may be prevented. Further, the semiconductor device 11 may be manufactured more easily than in the case where the via is formed in the lower semiconductor chip 120.

The upper semiconductor chip 130 may include an integrated circuit, e.g., a memory circuit, a logic circuit, or a combination thereof. The upper semiconductor chip 130 may be the same type as the lower semiconductor chip 120. The upper semiconductor chip 130 may have the same shape and area as the lower semiconductor chip 120. The upper semiconductor chip 130 may be arranged in a different direction from that of the lower semiconductor chip 120. For example, the lower semiconductor chip 120 and the upper semiconductor chip 130 may have a quadrangular plane. As illustrated in FIG. 1, a plane of the lower semiconductor chip 120 may have a longitudinal axis extending in one direction. A plane of the upper semiconductor chip 130 may have a longitudinal axis extending in another direction which is different from the one direction. Accordingly, the third pads 131 do not overlap the lower semiconductor chip 120 so that the lower surface 130b of the upper semiconductor chip 130 may serve as an active surface.

In the case where the upper surface 130a of the semiconductor chip 130 is an active surface, fine pitch of the semiconductor device 11 may be limited due to the bonding wires 140 connected to the upper surface 130a of the upper semiconductor chip 130. The bonding wires 140 may be damaged by a molding layer 150. According to an embodiment, since the lower surface 130b of the upper semiconductor chip 130 serves as an active surface, the damage to the bonding wires 140 may be prevented. Furthermore, fine pitch of the semiconductor device 11 may be possible. The upper semiconductor chip 130 may be electrically connected to the lower semiconductor chip 120 via the bonding wires 140, the substrate 110, and the first bumps 121. In the case where the lower surface 130b of the upper semiconductor chip 130 is an active surface, an electrical connection distance between the upper semiconductor chip 130 and the lower semiconductor chip 120 may be shorter than in the case where the upper surface 130a of the upper semiconductor chip 130 is an active surface. Therefore, parasitic capacitance between the upper semiconductor chip 130 and the lower semiconductor chip 120 may be reduced.

The molding layer 150 is provided on the inner surface 110a of the substrate 110, and may cover the upper semiconductor chip 130. The molding layer 150 may be further disposed between the substrate 110 and the lower semiconductor chip 120 so as to be provided between the first bumps 121. The molding layer 150 may extend onto the outer surface 110b of the substrate 110 through the windows 115 to cover the bonding wires 140 exposed on the outer surface 110b of the substrate 110. The molding layer 150 may mold the substrate 110, the lower semiconductor chip 120, the upper semiconductor chip 130, and the bonding wires 140. The molding layer 150 may include an insulative polymer such as an epoxy molding compound.

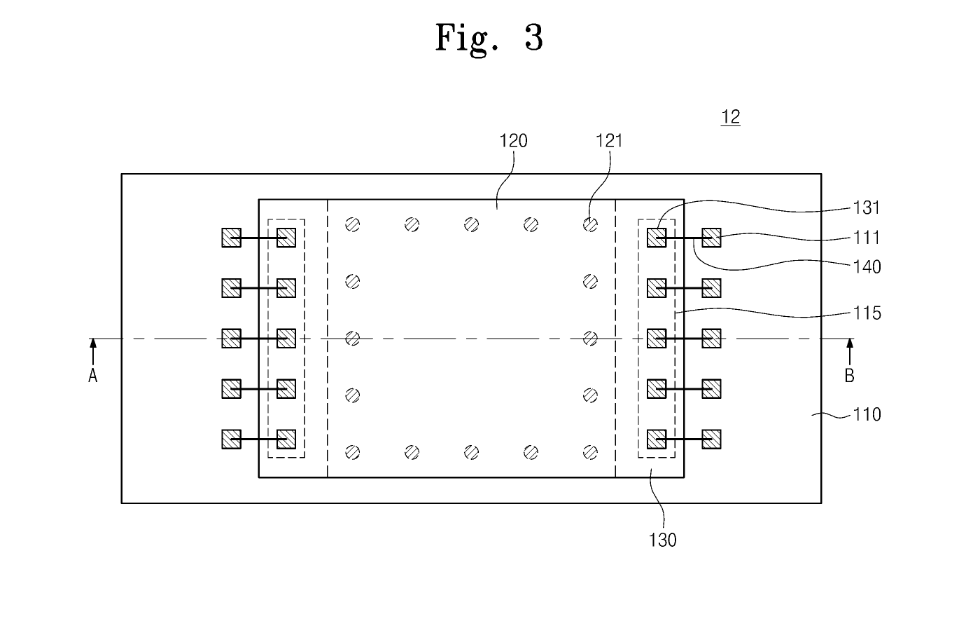

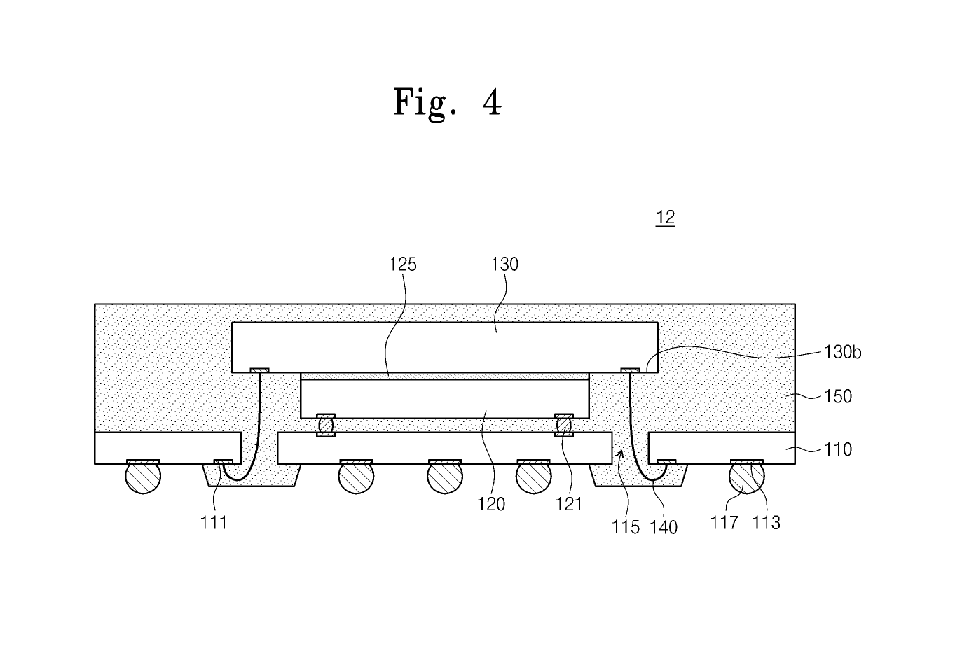

FIG. 3 is a planar view illustrating a semiconductor device according to another embodiment. FIG. 4 is a cross-sectional view of the semiconductor device taken along the line A-B of FIG. 3. The same description as mentioned above is omitted below.

Referring to FIGS. 3 and 4, a semiconductor device 12 may include a substrate 110, first bumps 121, a lower semiconductor chip 120, an upper semiconductor chip 130, bonding wires 140, and a molding layer 150. The lower semiconductor chip 120 may be mounted on the substrate 110 by the first bumps 121. The upper semiconductor chip 130 may be electrically connected to the substrate 110 by the bonding wires 140.

The upper semiconductor chip 130 may be a different type of chip from that of the lower semiconductor chip 120. For example, the upper semiconductor chip 130 may have a different function and/or a different size from those of the lower semiconductor chip 120. For example, a length of the upper semiconductor chip 130 in one direction may be greater than that of the lower semiconductor chip 120 in the one direction. The upper semiconductor chip 130 may be extended to be longer than the lower semiconductor chip 120. Since third pads 131 do not overlap the lower semiconductor chip 120, a lower surface 130b of the upper semiconductor chip 130 may serve as an active surface.

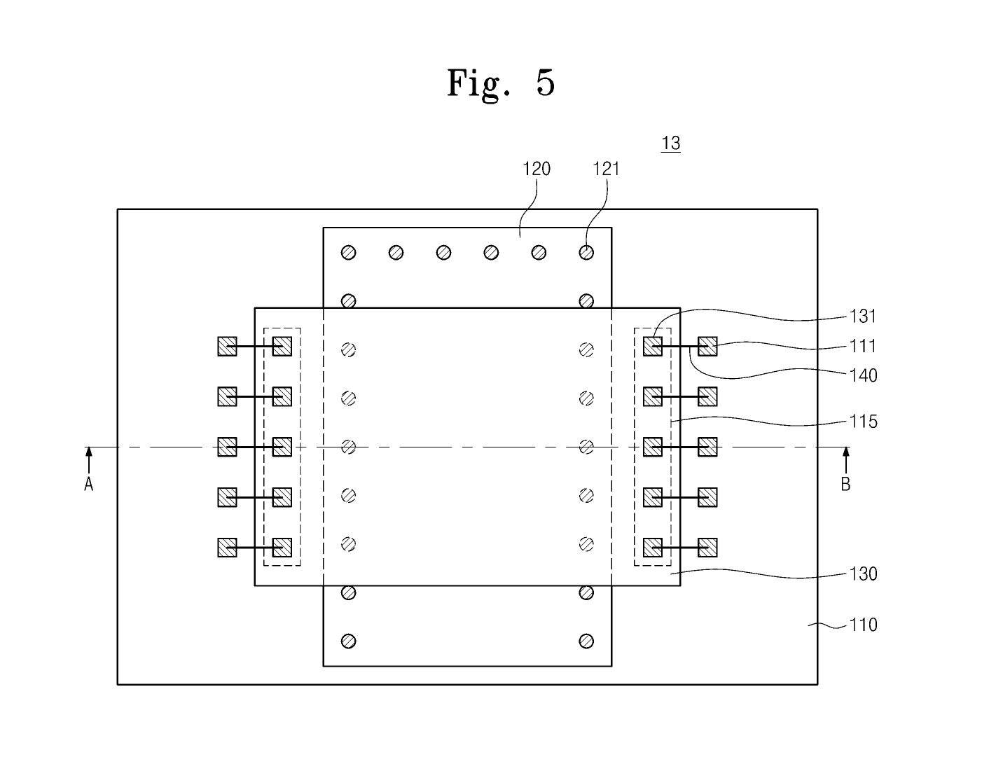

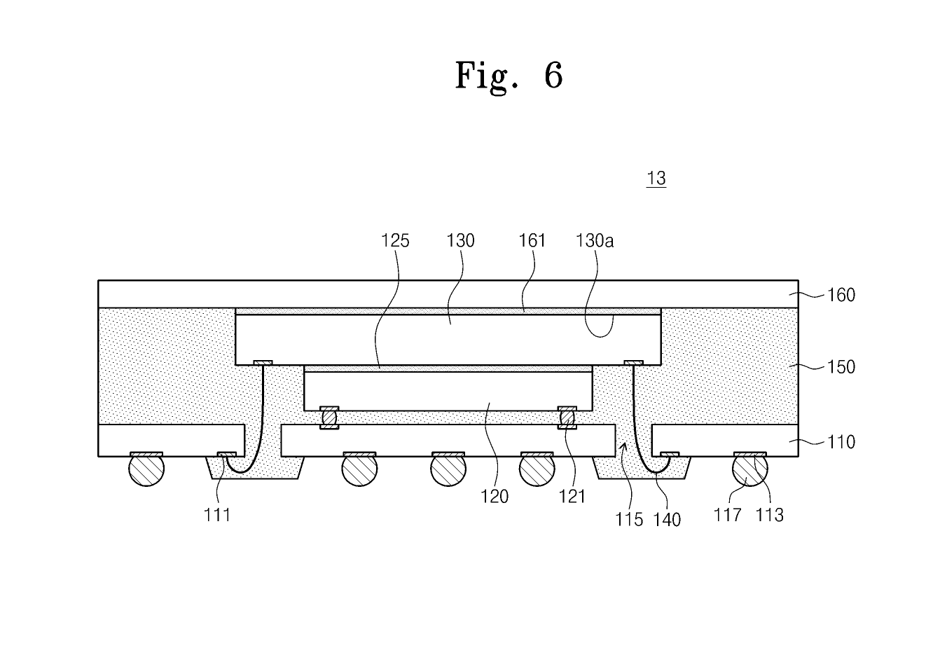

FIG. 5 is a planar view illustrating a semiconductor device according to another embodiment. FIG. 6 is a cross-sectional view of the semiconductor device taken along the line A-B of FIG. 5. The same description as mentioned above is omitted below.

Referring to FIGS. 5 and 6, a semiconductor device 13 may include a substrate 110, a lower semiconductor chip 120, an upper semiconductor chip 130, bonding wires 140, a molding layer 150, a heat transfer layer 161, and a heat slug (160). The lower semiconductor chip 120 may be flip-chip mounted on the substrate 110 by the first bumps 121. The upper semiconductor chip 130 may be flip-chip connected to the substrate 110 by the bonding wires 140. The upper semiconductor chip 130 may be the same type as the lower semiconductor chip 120. The upper semiconductor chip 130 may be arranged in a different direction from that of the lower semiconductor chip 120.

The heat transfer layer 161 may be provided on an upper surface 130a of the upper semiconductor chip 130. The heat transfer layer 161 may be arranged between the upper semiconductor chip 130 and the heat slug 160. The heat transfer layer 161 may include an adhesive material and/or a thermal interface material (TIM).

The heat slug 160 may be provided on the heat transfer layer 161. The heat slug 160 may include a material having low thermal resistance, such as metal. The heat generated in the upper semiconductor chip 130 may be dissipated to the outside through the heat transfer layer 161 and the heat slug 160. Therefore, the performance and/or reliability of the upper semiconductor chip 130 may be improved more than in the case where the heat slug 160 is not provided.

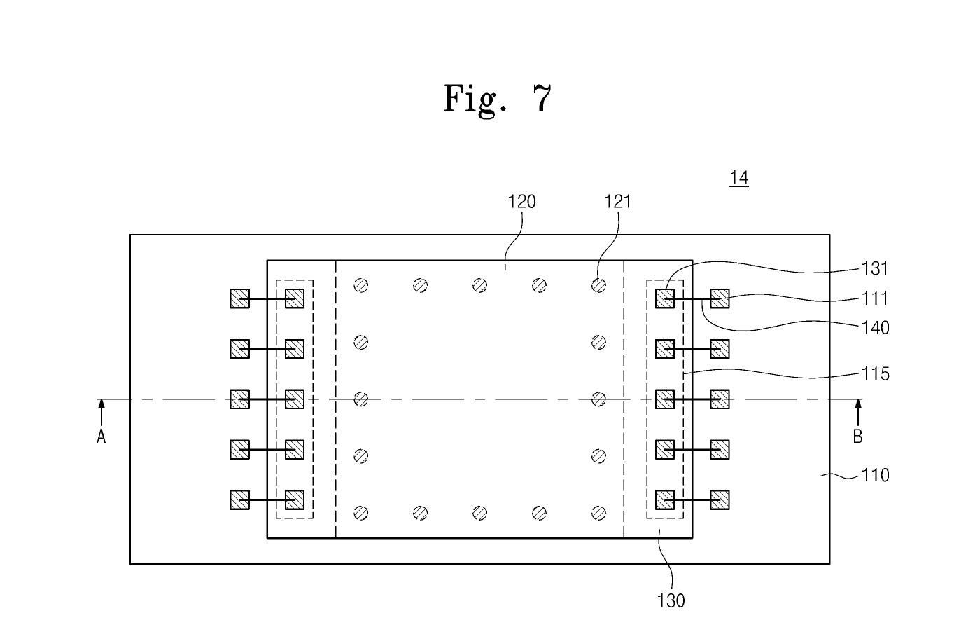

FIG. 7 is a planar view illustrating a semiconductor device according to another embodiment. FIG. 8 is a cross-sectional view of the semiconductor device taken along the line A-B of FIG. 7. The same description as mentioned above is omitted below.

Referring to FIGS. 7 and 8, a semiconductor device 14 may include a substrate 110, a lower semiconductor chip 120, an upper semiconductor chip 130, bonding wires 140, a heat transfer layer 161, and a heat slug 160. The lower semiconductor chip 120 may be flip-chip mounted on the substrate 110 by the first bumps 121. The upper semiconductor chip 130 may be electrically connected to the substrate 110 by the bonding wires 140. The upper semiconductor chip 130 may be a different type of chip from that of the lower semiconductor chip 120. The upper semiconductor chip 130 may be arranged in a different direction from that of the lower semiconductor chip 120. The heat generated in the upper semiconductor chip 130 may be dissipated to the outside through the heat transfer layer 161 and the heat slug 160.

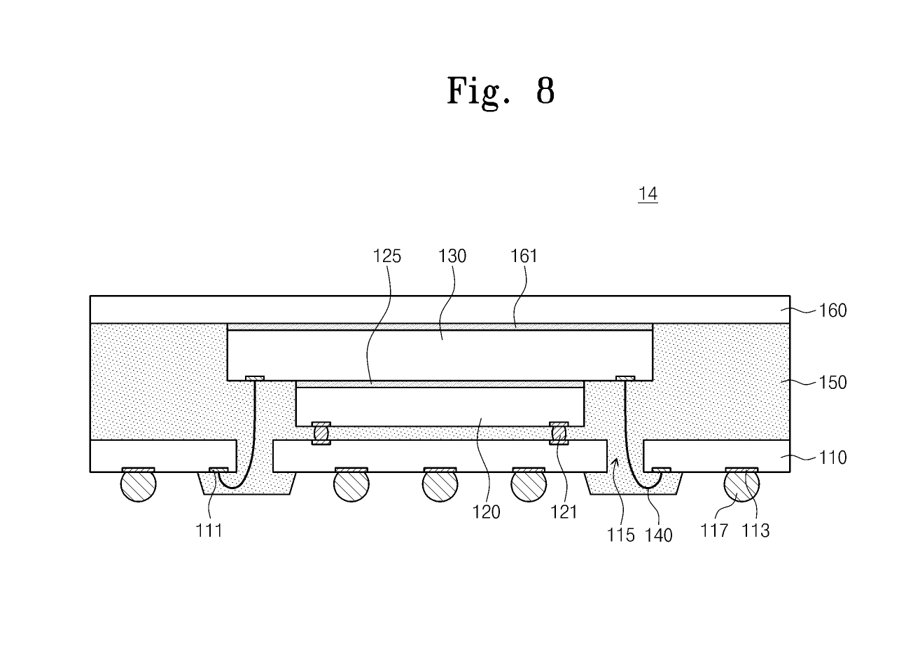

FIG. 9 is a cross-sectional view illustrating a semiconductor package according to an embodiment. The same description as mentioned above is omitted below.

Referring FIG. 9, a semiconductor package 1 may have a package on package (PoP) structure in which an upper package 10 is mounted on a lower package 20.

The lower package 20 may include a lower substrate 210, a semiconductor chip 220, connection parts 230, and a lower molding layer 240. The lower package 20 may be a flip-chip device in which the semiconductor chip 220 is face-down mounted on the lower substrate 210. The lower substrate 210 may be a printed circuit board having a circuit pattern. A fourth pad 211 and an external terminal 213 may be arranged on a lower surface of the lower substrate 210. The fourth pad 211 and the external terminal 213 may electrically connect the upper package 10 and/or the semiconductor chip 220 to an external electric device.

The semiconductor chip 220 may include an integrated circuit, e.g., a memory circuit, a logic circuit, or a combination thereof. Second bumps 221 are arranged between the lower substrate 210 and the semiconductor chip 220, and may electrically connect the semiconductor chip 220 to the lower substrate 210. The second bumps 221 may include conductive materials.

The connection parts 230 may be provided on the lower substrate 210. The connection parts 230 may contact solder balls 117 of the upper package 10 to electrically connect the upper package 10 to the lower package 20. The connection parts 230 include conductive materials, and may have the shape of solder or bump.

The lower molding layer 240 may fill gaps between the connection parts 230 and gaps between the second bumps 221 on the lower substrate 210. The lower molding layer 240 extends along a side of the semiconductor chip 220, and may seal the side of the semiconductor chip 220. The lower molding layer 240 may include an insulative polymer such as an epoxy molding compound.

A pore 250 may be provided between the lower package 20 and the upper package 10. In another example, the pore may not be provided.

The upper package 10 may be one of the semiconductor devices 11 to 14 described above with reference to FIGS. 1 to 8. The heat generated in the semiconductor chip 220 may be dissipated through a heat slug 160 via the connection parts 230, a substrate 110, a lower semiconductor chip 120, first bumps 125, an upper semiconductor chip 120, and a heat transfer chip 161. Therefore, the reliability of the semiconductor chip 220 may be improved. In the case where bonding wires 140 are connected to an inner surface 110a, the upper semiconductor chip 130 may be electrically connected to solder balls 117 through a via of the substrate 110. Since the bonding wires 140 of the upper package 10 contact first pads 111 provided on the outer surface 110b of the substrate 110, parasitic capacitance between the upper semiconductor chip 130 and the lower package 20 may be reduced more than in the case where the bonding wires 140 are connected to the inner surface 110a.

Hereinafter, a method for manufacturing a semiconductor device according to an embodiment will be described.

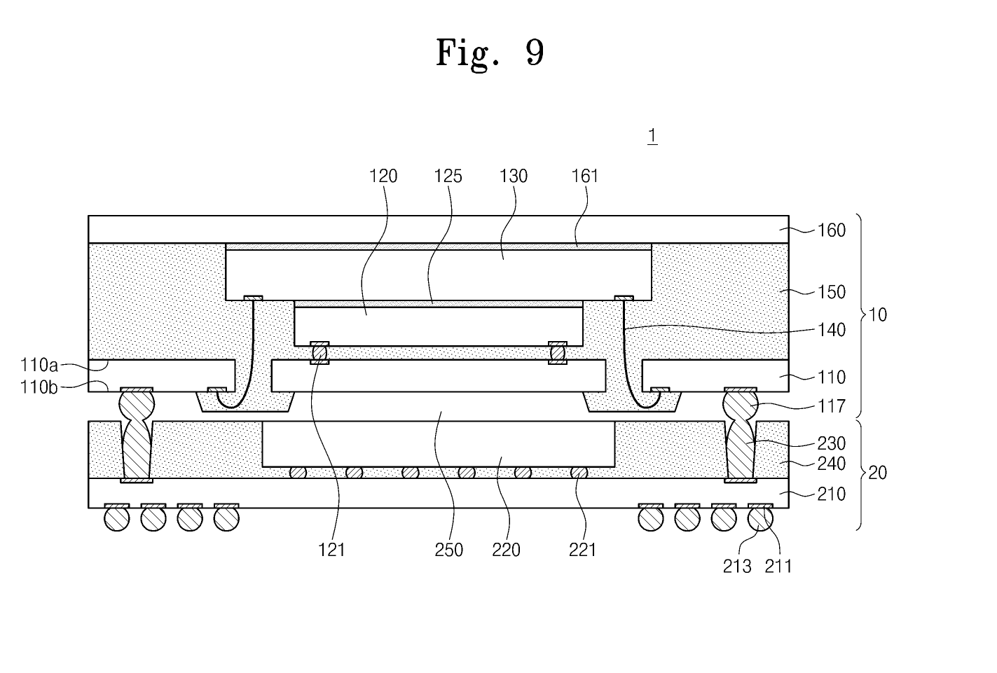

FIGS. 10 to 13 illustrate the method for manufacturing the semiconductor device according to an embodiment. The same description as mentioned above is omitted below.

Referring to FIG. 10, a heat transfer layer 161 and an upper semiconductor chip 130 may be sequentially formed on a heat slug 160. The heat slug 160 and the heat transfer layer 161 may be the same as or similar to the heat slug and the heat transfer layer described above with reference to FIGS. 5 and 6. The heat slug 160 may serve as a temporary substrate, and an additional process for attaching the heat slug 160 may be omitted. Third pads 131 may be provided on a lower surface 130b of the upper semiconductor chip 130. The upper semiconductor chip 130 may be attached to the heat transfer layer 161 so that an upper surface 130a faces the heat slug 160.

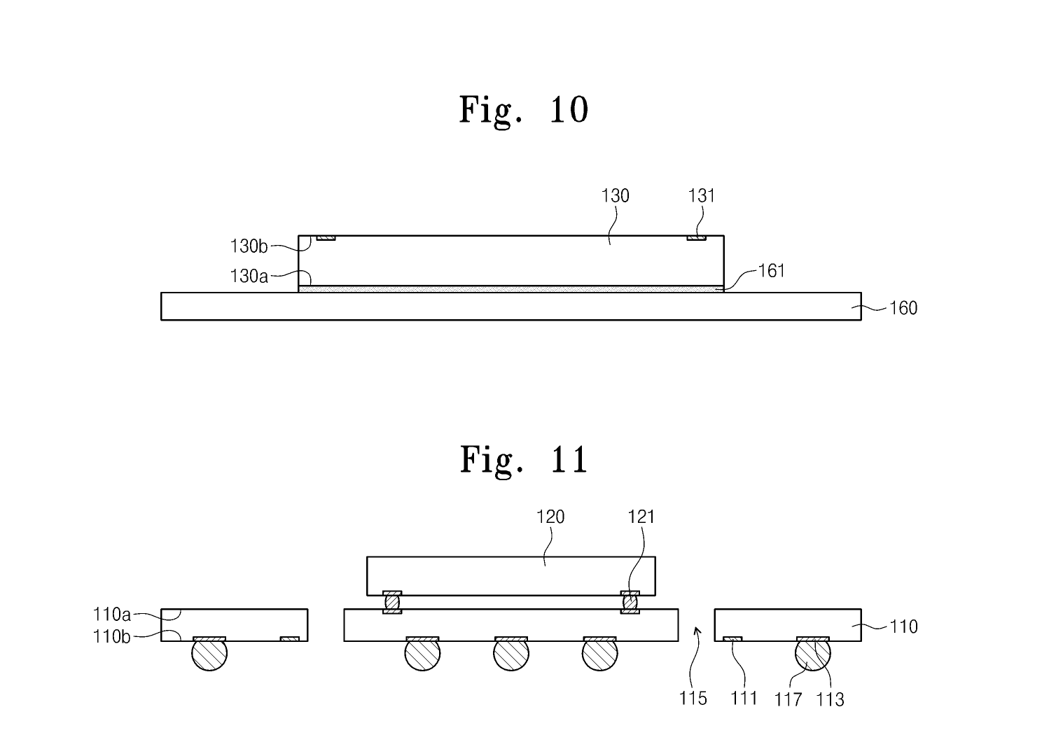

Referring to FIG. 11, a lower semiconductor chip 120 mounted on a substrate 110 may be prepared. First pads 111, second pads 113, and solder balls 117 may be provided on an outer surface 110b of the substrate 110. The substrate 110 may be a printed circuit board having windows 115 that passes therethrough. For example, the lower semiconductor chip 120 may be connected to an inner surface 110a of the substrate 110 by first bumps 121.

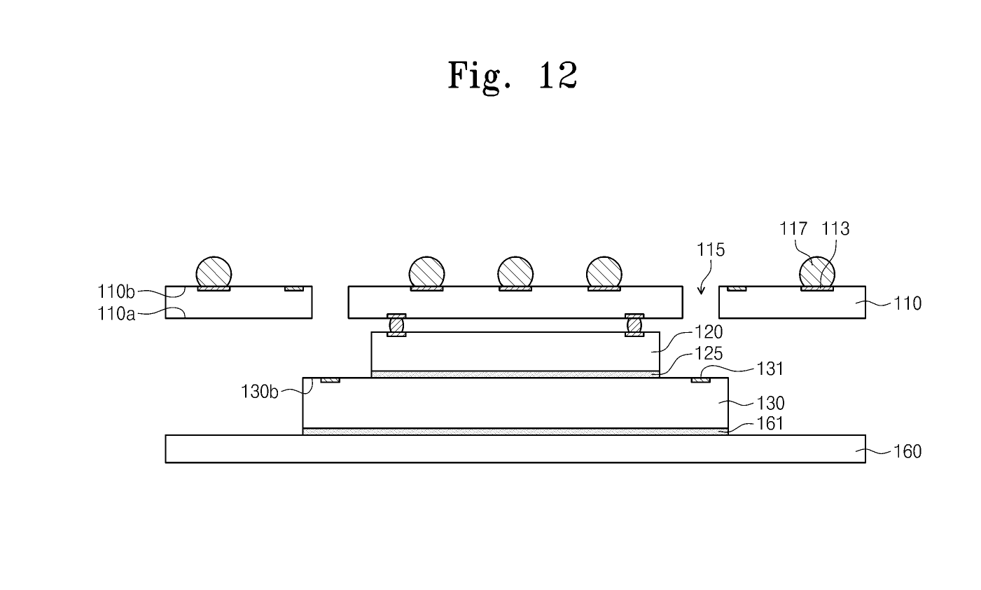

Referring to FIG. 12, the lower semiconductor chip 120 may be attached to the lower surface 130b of the upper semiconductor chip 130 by an adhesive film 125. The substrate 110 and the lower semiconductor chip 120 may be arranged such that the inner surface 110a of the substrate 110 face down. For example, in the case where the lower semiconductor chip 120 is the same type of chip as the upper semiconductor chip 130, the lower semiconductor chip 120 may be arranged in a different direction from that of the upper semiconductor chip 130. In another example, the upper semiconductor chip 130 may be a different type of chip from that of the lower semiconductor chip 120 and may be more extended than the lower semiconductor chip 120. The adhesive film 125 and the lower semiconductor chip 120 do not overlap the third pads 131. Thus, the third pads 131 may be exposed. The windows 115 may be positioned to vertically correspond to the third pads 131, so that the third pads 131 may be exposed. In another example, a heat slug 160 and a heat transfer layer 161 may be omitted. In this case, the lower semiconductor chip 120, the adhesive film 125, and the upper semiconductor chip 130 may be sequentially formed on the substrate 110 while the outer surface 110b of the substrate 110 faces down.

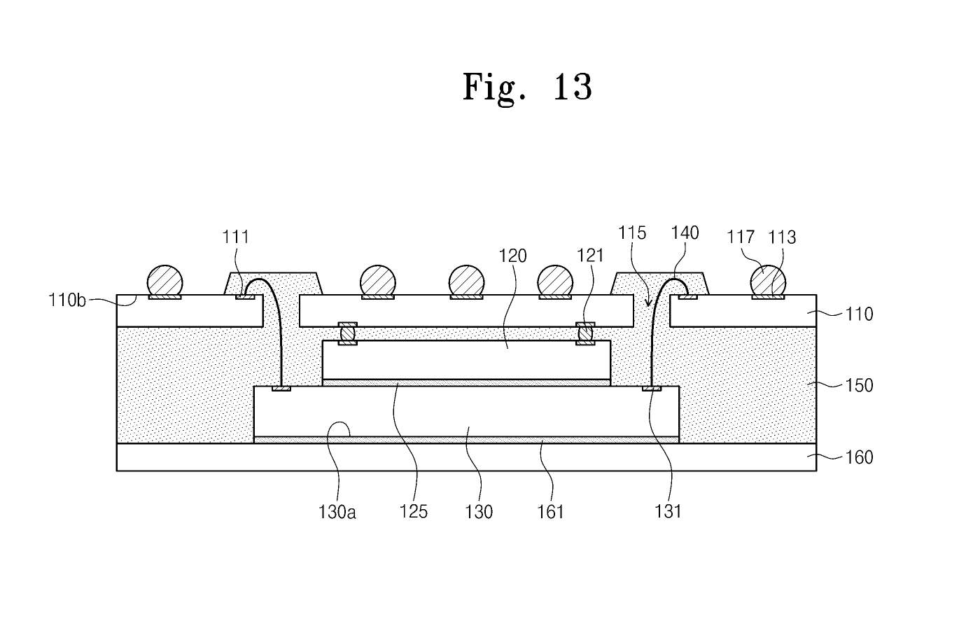

Referring to FIG. 13, bonding wires 140 and a molding layer 150 may be formed. For example, the bonding wires 140 may pass through the windows 115 and may connect the third pads 131 of the upper semiconductor chip 130 to the first pads 111 of the substrate 110. In the case where the bonding wires 140 are connected to the upper surface 130a of the upper semiconductor chip 130, the lower surface 130b of the semiconductor chip may face down during a process of forming the bonding wires 140 are formed. Accordingly, an overhang of the upper semiconductor chip 130 may be cracked. According to an embodiment, the upper surface 130a of the semiconductor chip 130 may face down during a process of forming the bonding wires 140. Therefore, the overhang part of the upper semiconductor chip 130 may be prevented from being cracked. The molding layer 150 may be formed to fill a gap between the heat slug 160 and the substrate 110. The molding layer 150 may partially extend onto the outer surface 110b of the substrate 110 through the windows 115 to cover the bonding wires 140 exposed on the outer surface 110b.

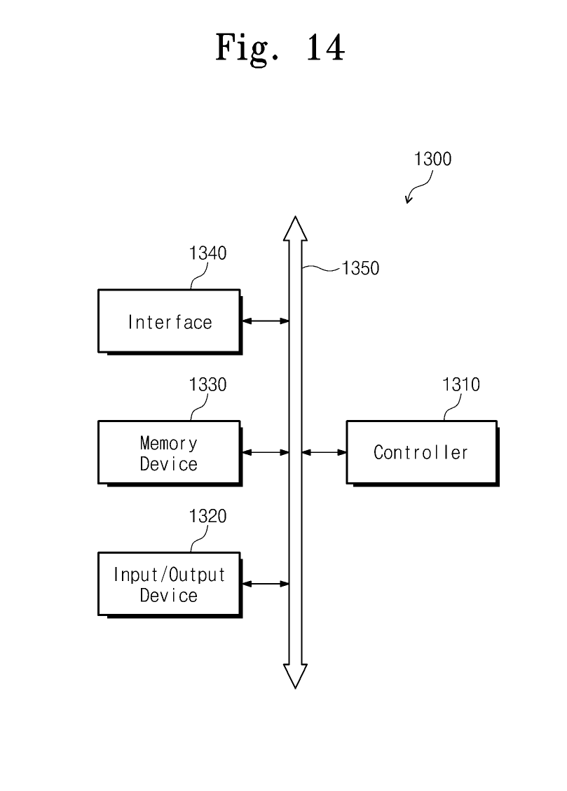

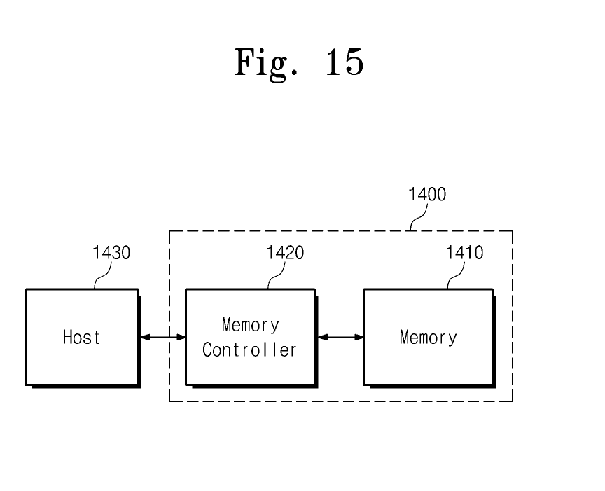

FIG. 14 is a block diagram illustrating an electronic device including a semiconductor device according to an embodiment. FIG. 15 is a block diagram illustrating a memory system including a semiconductor device according to an embodiment.

Referring to FIG. 14, an electronic system 1300 may include a controller 1310, an input/output device 1320, and a memory device 1330. The controller 1310, the input/output device 1320, and the memory device 1330 may be combined with each other through a bus 1350. The bus 1350 may be a passage through which data pass. For example, the controller 1310 may include at least one microprocessor, a digital signal processor, a microcontroller, and at least one of logic elements capable of performing the same functions as the microprocessor, the digital signal processor, and the microcontroller. The controller 1310 and the memory device 1330 may include any one of the semiconductor devices 11 to 14 according to embodiments. The input/output device 1320 may include at least one of a keypad, a keyboard, and a display device. The memory device 1330 stores data. The memory device 1330 may include data and/or commands executed by the controller 1310. The memory device 1330 may include a volatile memory device and/or a nonvolatile memory device. The memory device 1330 may be formed as a flash memory. For example, a flash memory to which the technology is applied may be installed in an information processing system such as a mobile device or a desktop computer. This flash memory may be configured as a solid state drive (SSD). In this case, the electronic system 1300 may stably store a large amount of data in the flash memory system. The electronic system 1300 may further include an interface 1340 for transmitting data to a communication network or receiving data therefrom. The interface 1340 may be operated by wire or wirelessly. For example, the interface 1340 may include an antenna or a wired/wireless transceiver. Further, it would be obvious to those skilled in the art that the electronic system 1300 may be further provided with an application chipset, a camera image processor (CIS), and an input/output device which are not illustrated in the drawings.

The electronic system 1300 may be implemented as a mobile system, a personal computer, an industrial computer, or a logic system for performing various functions. For example, the mobile system may be one of a personal digital assistant (PDA), a portable computer, a web tablet, a mobile phone, a wireless phone, a laptop computer, a memory card, a digital music system, and an information transmitting/receiving system. In the case where the electronic system 1300 is capable of performing wireless communication, the electronic system 1300 may be used according to a communication interface protocol such as a third generation communication system, for example CDMA, GSM, NADC, E-TDMA, WCDMA, and CDMA2000.

Referring to FIG. 15, a memory card 1400 may include a nonvolatile memory device 1410 and a memory controller 1420. The nonvolatile memory device 1410 and the memory controller 1420 may store data or read stored data. The nonvolatile memory device 1410 may include any one of the semiconductor devices 11 to 14 according to embodiments. The memory controller 1420 may control the nonvolatile memory device 1410 so that the nonvolatile memory device 1410 reads the stored data or writes data in response to a read/write request from a host.

A semiconductor package according to an embodiment may include a flip-chip mounted lower semiconductor chip and an upper semiconductor chip. The heat generated in the lower semiconductor chip can be dissipated to a substrate through connection terminals. The heat generated in the upper semiconductor chip can be dissipated to the outside through a heat transfer layer and a heat slug. Therefore, the reliability and performance of the semiconductor package can be improved. The parasitic capacitance of the upper and lower semiconductor chips can be reduced. According to a method for manufacturing a semiconductor package according to an embodiment, an overhang part of the upper semiconductor chip can be prevented from being cracked.

The above-disclosed subject matter is to be considered illustrative and not restrictive, and the appended claims are intended to cover all such modifications, enhancements, and other embodiments, which fall within the true spirit and scope of the exemplary embodiments. Thus, to the maximum extent allowed by law, the scope of the exemplary embodiments is to be determined by the broadest permissible interpretation of the following claims and their equivalents, and shall not be restricted or limited by the foregoing detailed description.

1. A semiconductor package comprising:
a substrate having an outer surface and an inner surface which opposes the outer surface, wherein the substrate is provided with a plurality of windows which pass through the inner surface and the outer surface;
a lower semiconductor chip disposed on the inner surface of the substrate;
an upper semiconductor chip disposed on the lower semiconductor chip, wherein the upper semiconductor chip has a lower surface which faces the substrate and an upper surface which opposes the lower surface;
a plurality of connection terminals disposed between the substrate and the lower semiconductor chip, wherein the connection terminals electrically connect the lower semiconductor chip to the substrate; and
a plurality of bonding wires which pass through the windows and connect the lower surface of the upper semiconductor chip to the outer surface of the substrate.

2. The semiconductor package of claim 1, further comprising:
a heat slug disposed on the upper surface of the upper semiconductor chip; and
a heat transfer layer disposed between the upper semiconductor chip and the heat slug.

3. The semiconductor package of claim 1, wherein the upper semiconductor chip comprises a plurality of connection pads disposed on both ends of the lower surface of the upper semiconductor chip to contact the bonding wires, and
wherein the lower semiconductor chip exposes the connection pads.

4. The semiconductor package of claim 3, wherein the windows are arranged in a vertical location in relation to the connection pads.

5. The semiconductor package of claim 1, wherein a plane of the lower semiconductor chip has a longitudinal axis extending in one direction, and a plane of the upper semiconductor chip has a longitudinal axis extending in another direction which is different from the one direction.

6. The semiconductor package of claim 1, further comprising:
a molding layer disposed on the inner surface of the substrate,
wherein the molding layer seals the lower semiconductor chip, the upper semiconductor chip, the connection terminals, and the bonding wires.

7-11. (canceled)

12. A semiconductor package comprising:
a substrate which comprises a plurality of windows passing through the substrate;
a lower semiconductor chip disposed on the substrate;
an upper semiconductor chip disposed on the lower semiconductor chip; and
a heat slug disposed on the upper semiconductor chip,
wherein the upper semiconductor chip is electrically connected to the substrate through a plurality of connection terminals.

13. The semiconductor package of claim 12, further comprising:
a heat transfer layer disposed between the upper semiconductor chip and the heat slug.

14. The semiconductor package of claim 12, wherein a plurality of first pads disposed in the substrate are electrically connected to a plurality of second pads disposed in the upper semiconductor chip through a plurality of bonding wires.

15. The semiconductor package of claim 14, wherein the bonding wires electrically connect the first pads to the second pads by passing through the windows.

16. The semiconductor package of claim 14, further comprising:
a molding layer disposed on the substrate,
wherein the molding layer seals the lower semiconductor chip, the upper semiconductor chip, the connection terminals, and the bonding wires.

17. The semiconductor package of claim 14, wherein the windows are arranged in a vertical location in relation to the second pads.

18. The semiconductor package of claim 14, wherein the bonding wires connect the upper semiconductor chip to the substrate through the windows.

19. The semiconductor package of claim 14, wherein the lower semiconductor chip is disposed such that the second pads are exposed.

20. The semiconductor package of claim 12, wherein a plane of the lower semiconductor chip has a longitudinal axis extending in one direction, and a plane of the upper semiconductor chip has a longitudinal axis extending in another direction which is different from the one direction.
